(19) United States
(12) Patent Application Publication
(10) Pub. No.: US 2010/0079651 A1
(43) Pub. Date: Apr. 1, 2010

(54) IMAGE SENSOR AND METHOD FOR MANUFACTURING THE SAME

(76) Inventor: Gun-Hyuk Lim, Songpa-gu (KR)

Correspondence Address: SHERR & VAUGHN, PLLC, 620 HERNDON PARKWAY, SUITE 320, HERNDON, VA, 20170, US

(21) Appl. No.: 12/568,876

(22) Filed: Sep. 29, 2009

(30) Foreign Application Priority Data
Sep. 30, 2008 (KR) 10-2008-0096045

(51) Int. Cl. H04N 5/335; H01L 21/28

(52) U.S. Cl. 348/308; 438/73; 348/E05.091; 257/E21.158

(57) ABSTRACT

An image sensor and a method of manufacturing an image sensor. An image sensor may include a first pixel. A first pixel may include a first photodiode and a first readout circuit. An image sensor may include a second pixel. A second pixel may include a second photodiode and a second readout circuit, which may be disposed at one side of a first pixel. An image sensor may include a different threshold voltage of a first drive transistor relative to a threshold voltage of a second drive transistor. A method of manufacturing an image sensor may include forming a first pixel having a first photodiode and a first readout circuit, and may include forming a second pixel having a second photodiode and a second readout circuit, wherein a threshold voltage of a first drive transistor relative to a threshold voltage of a second drive transistor is different.

The present application claims priority under 35 U.S.C. 119 to Korean Patent Application No. 10-2008-0096045 (filed on Sep. 30, 2008) which is hereby incorporated by reference in its entirety.

### BACKGROUND

Embodiments relate to electric devices and methods thereof. Some embodiments relate to an image sensor and a method of manufacturing the same.

An image sensor may be a semiconductor device which may convert an optical image into an electric signal. An image sensor may be classified as a charge coupled device (CCD) or a complementary metal oxide semiconductor (CMOS) image sensor (CIS). A CMOS image sensor may include a photodiode and a MOS transistor in each unit pixel, and may sequentially detect electric signals of each unit pixel in a switching scheme to realize images. A CIS (CMOS image sensor) may include a photodiode area that receives a light signal to convert the light signal into an electric signal, and a transistor area that processes the electric signal. A CIS may reproduce colors by obtaining R/B/G colors from four pixels having substantially the same size.

However, outputs of R/B/G colors may vary depending on a junction profile of a photodiode, a wavelength of light, and/or a structure of a CIS. If a color has a relatively low-level output, relatively more gain may be needed to increase the output of the color and variable amplification may need to be performed for each color. Noise components may also be amplified, such that relative image quality of a CIS may be relatively degraded.

Accordingly, there is a need for an image sensor, and a method of manufacturing an image sensor, which may maximize relative quality and/or which may substantially constantly maintain a color output of each pixel, for example, by controlling a gain according to each color.

### SUMMARY

Embodiments relate to an image sensor and a method of manufacturing an image sensor. According to embodiments, an image sensor and a method of manufacturing the same may maximize relative image quality. In embodiments, an image sensor and a method of manufacturing the same may substantially constantly maintain a color output of each pixel by, for example, controlling a gain according to each color.

Embodiments relate to an image sensor. According to embodiments, an image sensor may include a first pixel having a first photodiode and a first readout circuit. In embodiments, an image sensor may include a second pixel having a second photodiode and a second readout circuit, and may be disposed at one side of a first pixel. In embodiments, a threshold voltage of a first drive transistor of a first readout circuit may be different than a threshold voltage of a second drive transistor of a second readout circuit.

Embodiments relate to a method of manufacturing an image sensor. According to embodiments, a method of manufacturing an image sensor may include forming a first pixel having a first photodiode and a first readout circuit. In embodiments, a method of forming an image sensor may include forming a second pixel having a second photodiode and a second readout circuit, which may be disposed at one side of a first pixel. In embodiments, a method of manufacturing an image sensor may include a threshold voltage of a first drive transistor of a first readout circuit that may be different than a threshold voltage of a second drive transistor of a second readout circuit.

### DRAWINGS

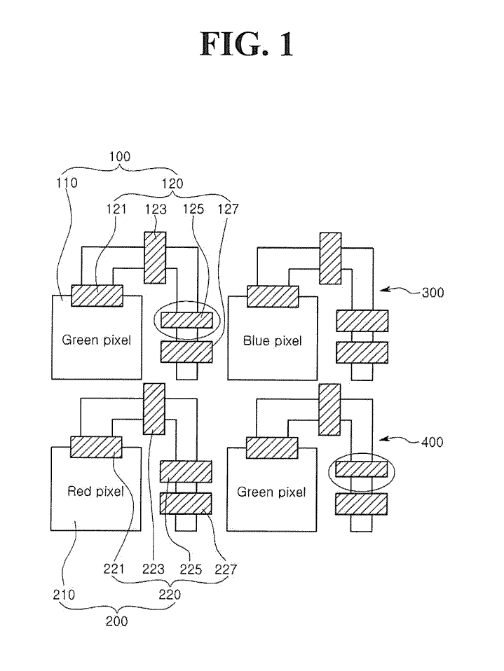

Example FIG. 1 illustrates an image sensor in accordance with embodiments.

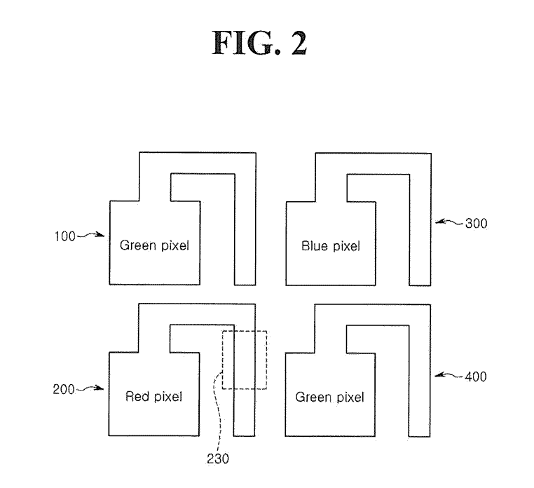

Example FIG. 2 illustrates an image sensor in accordance with embodiments.

### DESCRIPTION

Embodiments relate to an image sensor. Example FIG. 1 illustrates an image sensor in accordance with embodiments. According to embodiments, an image sensor may include a first pixel, such as first pixel 100. In embodiments, first pixel 100 may include first photodiode 110 and first readout circuit 120. In embodiments, an image sensor may include a second pixel, such as second pixel 200. Second pixel 200 may include second photodiode 210 and second readout circuit 220, and may be disposed at one side of first pixel 100 in accordance with embodiments. In embodiments, a threshold voltage of first drive transistor 125 of first readout circuit 120 may be different than a threshold voltage of second drive transistor 225 of second readout circuit 220.

According to embodiments, a channel length may be selectively relatively reduced and/or enlarged to adjust a threshold voltage (Vth) of a drive transistor that may amplify an output of a pixel. In embodiments, a gain may be controlled according to each color, such that the color output of each pixel may be substantially constantly maintained. In embodiments, each color may have substantially the same output level, and variable amplification for each color may not be required. In embodiments, noise variation may not substantially occur among the colors. In embodiments, relative image quality of an image sensor may be maximized.

Embodiments relate to a method of manufacturing an image sensor. According to embodiments, a method of manufacturing an image sensor may include forming a first pixel, such as first pixel 100. In embodiments, first pixel 100 may include first photodiode 110 and first readout circuit 120. In embodiments, first pixel 100 may be formed over an active area. In embodiments, first photodiode 110 may be formed using an ion implantation process. First photodiode 110 may correspond to a color, such as the color green in accordance with embodiments.

According to embodiments, a channel ion implantation process may be performed, and polysilicon may be formed. In embodiments, photo and/or etching processes may be performed to form a first readout circuit, such as first readout circuit 120. In embodiments, first readout circuit 120 may include first transfer transistor gate 121, first reset transistor gate 123, first drive transistor gate 125 and/or first select transistor gate 127.

According to embodiments, second pixel 200, third pixel 300 and/or fourth pixel 400 may be aligned at one side of first pixel 100. In embodiments, second pixel 200 may correspond to a color, such as the color red, third pixel 300 may correspond to a color, such as the color blue, and fourth pixel 400 may correspond to a color, such as the color green.

According to embodiments, second pixel 200 may include second transfer transistor gate 221, second reset transistor gate 223, second drive transistor gate 225 and/or second select transistor gate 227. In embodiments, a readout circuit of third pixel 300 and/or of fourth pixel 400 may, for example, have a substantially similar structure to the structure of first readout circuit 120 of first pixel 100.

According to embodiments, a threshold voltage of first drive transistor 125 of first readout circuit 120 may be different than a threshold voltage of second drive transistor 225 of second readout circuit 220. In embodiments, a critical dimension (CD) of first drive transistor 125 of first readout circuit 120 may be different than a critical dimension of second drive transistor 225 of second readout circuit 220. In embodiments, an output of a pixel may be inversely proportional to a threshold voltage of a drive transistor, and/or a gain of a drive transistor may be inversely proportional to a threshold voltage of a drive transistor. In embodiments, if a drive transistor includes a relatively higher threshold voltage, a gain may be relatively reduced, such that an output is relatively reduced. In embodiments, an output level of R/B/G colors may be controlled to be relatively increased and/or decreased.

According to embodiments, a channel length may be selectively relatively reduced and/or enlarged to adjust a threshold voltage (Vth) of a drive transistor that may amplify an output of a pixel. In embodiments, a gain may be controlled according to each color, such that the color output of each pixel may be substantially constantly maintained. In embodiments, each color may have substantially the same output level, and variable amplification for each color may not be required. In embodiments, noise variation may not substantially occur among the colors. In embodiments, image quality of the image sensor may be maximized. In embodiments, a CD of a first drive transistor 125 of a first pixel 100, which may correspond to a green color, may be relatively reduced to relatively lower a threshold voltage, thereby relatively increasing sensitivity of a green color.

Embodiments relate to an image sensor and a method of manufacturing the same. Example FIG. 2 illustrates an image sensor in accordance with embodiments. According to embodiments, an additional channel implantation process may be performed which may adjust a threshold voltage (Vth) of a drive transistor which may amplify an output of a pixel. In embodiments, a gain may be controlled according to each color, such that a color output of each pixel may be substantially constantly maintained. In embodiments, each color may have substantially the same output level, and variable amplification for each color may not be required. In embodiments, noise variation may not substantially occur among the colors. In embodiments, relative image quality of the image sensor may be maximized.

According to embodiments, an additional ion implantation area may be formed, such as additional ion implantation area 230. In embodiments, additional ion implantation area 230 may be formed over an area of second drive transistor 225 of second pixel 200, which may correspond to the color red. In embodiments, a threshold voltage of second drive transistor 225 may relatively increase, and/or may relatively lower sensitivity to the color red. In embodiments, additional ion implantation area 230 may be formed by a channel implantation process before a gate is formed. In embodiments, additional ion implantation area 230 may be formed over an area where second drive transistor 225 of second pixel 200 may be later formed. A P-type additional ion implantation area 230 may be formed for an NMOS in accordance with embodiments.

According to embodiments, an additional ion implantation area may include a type of ions that are substantially opposite to a type of ions implanted over a channel ion implantation area. In embodiments, a channel width may be narrowed, such that a threshold voltage may be lowered. In embodiments, a center of a channel implantation area for second drive transistor 225 may be covered with an ion implantation mask, and ions having a type substantially opposite to a type of ions implanted over a channel ion implantation area may be additionally implanted, for example over two sides of a channel ion implantation area relative to its center, thereby reducing a width of a channel area.

According embodiments, a channel length may be selectively relatively reduced and/or enlarged to adjust a threshold voltage (Vth) of a drive transistor which may amplify an output of the pixel. In embodiments, a gain may be controlled according to each color, such that a color output of each pixel may be substantially constantly maintained. In embodiments, relative image quality may be maximized.

According to embodiments, an additional channel implantation process may be performed to adjust a threshold voltage (Vth) of a drive transistor which may amplify an output of a pixel. In embodiments, a gain may be controlled according to each color, such that a color output of each pixel may be substantially constantly maintained. In embodiments, relative image quality may be maximized.

In embodiments, each color may have substantially the same output level, and variable amplification for each color may not he required. In embodiments, noise variation may not substantially occur among the colors. In embodiments, relative image quality of an image sensor may maximized.

It will be obvious and apparent to those skilled in the art that various modifications and variations can he made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a first pixel comprising a first photodiode and a first readout circuit including a first drive transistor; and
forming a second pixel comprising a second photodiode and a second readout circuit including a second drive transistor,
wherein a threshold voltage of said first drive transistor is different than a threshold voltage of said second drive transistor.

2. The method of claim 1, wherein said second pixel is formed at one side of said first pixel.

3. The method of claim 1, wherein a channel length of said first drive transistor is different that a channel length of said second drive transistor.

4. The method of claim 1, wherein a critical dimension of said first drive transistor is different than a critical dimension of said second drive transistor.

5. The method of claim 1, comprising a channel implantation process performed for said first drive transistor and said second drive transistor, wherein a width of a channel implantation area formed over an area of said first drive transistor is different than a width of a channel implantation area formed over an area of said second drive transistor.

6. The method of claim 5, wherein said channel implantation process performed for said second drive transistor comprises an additional channel implantation process performed separately from said channel implantation process performed for said first drive transistor.

7. The method of claim 6, wherein said additional channel implantation process comprises using substantially the same type of ions relative to a type of ions used for said channel implantation process for said second drive transistor.

8. The method of claim 6, wherein said additional channel implantation process comprises using a substantially opposite type of ions relative to a type of ions used for said channel implantation process for said second drive transistor.

9. The method of claim 6, wherein an additional ion implantation area is formed over an area where said second drive transistor is formed.

10. The method of claim 1, wherein said first pixel is formed over an active area.

11. The method of claim I, wherein said photodiode corresponds to one of a red, blue and green color.

12. The method of claim 1, wherein:
said first readout circuit comprises at least one of a first transistor gate, a first reset transistor gate and a first select transistor gate; and
said second readout circuit comprises at least one of a second transistor gate, a second reset transistor gate and a second select transistor gate.

13. An apparatus comprising:
a first pixel comprising a first photodiode and a first readout circuit including a first drive transistor; and
a second pixel comprising a second photodiode and a second readout circuit including a second drive transistor,
wherein a threshold voltage of said first drive transistor is different that a threshold voltage of said second drive transistor.

14. The apparatus of claim 13, wherein:
said first pixel corresponds to a green color and is formed over an active area; and
said second pixel corresponds to a red color and is disposed at one side of said first pixel.

15. The apparatus of claim 13, wherein a critical dimension of said first drive transistor is different than a critical dimension of said second drive transistor.

16. The apparatus of claim 13, wherein a width of a channel implantation area formed over an area of said first drive transistor is different than a width of a channel implantation area formed over an area of the second drive transistor.

17. The apparatus of claim 13, wherein a channel length of said first drive transistor is different than a channel length of said second drive transistor.

18. The apparatus of claim 13, wherein:
said first readout circuit comprises at least one of a first transistor gate, a first reset transistor gate and a first select transistor gate; and
said second readout circuit comprises at least one of a second transistor gate, a second reset transistor gate and a second select transistor gate.

19. The apparatus of claim 13, comprising an additional ion implantation area.

20. The apparatus of claim 19, wherein said additional ion implantation area comprises at least one of:
substantially the same type of ions relative to a type of ions used for said second drive transistor; and
a substantially opposite type of ions relative to a type of ions for said second drive transistor.
